(19) United States
(12) Patent Application Publication
(10) Pub. No.: US 2001/0033123 A1
(43) Pub. Date: Oct. 25, 2001

(54) Piezoelectric oscillator assembly

(76) Inventor: Herbert J. Thanner, Graz (AT)

Correspondence Address: Kevin W. Guynn, SONNENSCHEIN NATH & ROSENTHAL, Wacker Drive Station, Sears Tower, P.O. Box #061080, Chicago, IL, 60606-1080, US

(21) Appl. No.: 09/802,000

(22) Filed: Mar. 8, 2001

(30) Foreign Application Priority Data
Mar. 8, 2000 (AT) A 385/2000

(51) Int. Cl. H01L 41/04

(52) U.S. Cl. 310/321; 310/348; 310/354

(57) ABSTRACT

A piezoelectric resonator arrangement comprises a mount having at least two mounting elements on a base structure and at least one laminar piezoelectric resonator that is clamped between the mounting elements, of which at least one impinges on the resonator with a force. In order to obtain the oscillation and resonance characteristics in a manner as free as possible of influence from the mounting or, respectively, contacting, and over a large temperature range in order also to minimize the temperature-caused hysteresis of the resonance characteristics, the mounting elements abut immediately and directly on the resonator and fix this resonator in the arrangement without the use of adhesive, and the points of contact of the mounting elements with the resonator are located essentially in one plane that lies essentially parallel to the plane of the resonator, and, in addition, the mounting and contacting forces exerted by the mounting elements lie essentially parallel to the plane of the resonator.

### BACKGROUND OF THE INVENTION

The invention relates to a piezoelectric resonator arrangement comprising a mount having at least two mounting elements on a base structure and at least one platelike, piezoelectric resonator that is clamped between the mounting elements, of which at least one is pressed against the resonator by a force.

In addition to the effectively acting material constants and the physical dimensions, the resonance frequency of a piezoelectric resonator is decisively dependent on the interaction with its environment (for example: pressure, temperature, mass load). From this, two fundamentally different areas of application naturally arise. On the one hand, piezoelectric resonators are used as a frequency standard, whereby the resonator is standardly located in the feedback branch of an oscillator, and thereby stabilizes the oscillator frequency in the vicinity of the resonance frequency. In this application, the influences of the environment on the resonance frequency are kept as constant as possible by a hermetically sealed housing that is either filled with a protective gas or is evacuated. On the other hand, piezoelectric resonators are used as sensor elements, whereby from the measured changes of the resonance characteristics, conclusions are drawn concerning the physical or, respectively, chemical characteristics, or, respectively, the chronological modification thereof, of the environment. In both areas of application, a mounting and contacting of the resonator is required.

In the case of the frequency standard, the resonator is standardly mounted in standardized housings, whereby the electrodes are glued to the supply lines in electrically conductive fashion, and the resonator therefore cannot be exchanged. In the case of the microbalance sensor application (QCM B Quartz Crystal Microbalance), the resonator (thickness shear oscillator) is built into correspondingly constructed mounts, which standardly can be disassembled. The resonator is thereby contacted at both sides, and held stably in position, using resilient contact elements that exert holding forces (FIG. 1) that act axially on the resonator, thus also pressing the resonator against the mounting part connected to ground potential (for example, the microbalance sensor mount of the company Leybold Inficon).

Given this ‘axial’ contacting or, respectively, mounting, temperature variations result not only in different thermal expansions between the resonator surface and the mount, but also in changes of the contact forces of the spring elements, and thus in undefined transition resistances. In order to minimize as far as possible thermally caused influences on the resonance frequency, temperature-compensated blanks (e.g., quartz AT blanks) are used, and also the mount is cooled or, respectively, thermostatized during the measurement.

An axial contacting is also present in the mount of the piezoelectric resonator according to DE 34 27 646 A, in which the resonator lies with one of its flat covering surfaces on lugs of the resonator mount and is fixed thereon by gluing. Here as well, the oscillation characteristics of the crystal are therefore influenced in an undesired manner by axial contacting and mounting. The mount according to JP 57-92913 A is similar both in its construction and also in its negative effects on the oscillation characteristics of the resonator. Here as well, a discoid resonator lamina is positioned and fixed by axial application and gluing with the mounting elements; additional positioning aids also being present on said mounting elements in the form of elements abutting the lateral surfaces of the resonator.

Finally, mention is also made of the construction stated and presented as prior art in the cited Japanese laid open print, in which two mounting lugs are present having parallel longitudinal slits for the installation of the resonator lamina. The lower, and if necessary also the upper, covering surface of the resonator lamina lies on the edge of the longitudinal slit with a part of its surface, so that here as well a negative influence on the oscillation characteristics is possible, in particular given the (typically likewise provided) gluing of the resonator lamina to the mounting lugs.

### SUMMARY OF THE INVENTION

The object of the invention is to propose a simple arrangement for the mounting or, respectively, contacting of a piezoelectric resonator in which the oscillation and resonance characteristics remain as free as possible of influence from the mounting or, respectively, contacting. In addition, this advantage is to be provided over a large temperature range, in order thereby also to minimize the temperature-caused hysteresis of the resonance characteristics.

The first object is solved according to the present invention in that the mounting elements abut immediately and directly on the resonator, and fix the resonator in the arrangement without the use of an adhesive, and in that the points of contact of the mounting elements with the resonator lie essentially in one plane, said plane being essentially parallel to the plane of the resonator, and in that the mounting and contacting forces exerted by the mounting elements lie essentially parallel to the plane of the resonator. The use of the resonator is thereby significantly simplified, because no additional gluings need be provided that form an intermediate layer between the mounting elements and the resonator material. The mounting forces, and if necessary also the contacting forces, are already given by the mounting elements alone. This also enables the resonator to be exchanged in a simple manner without destruction. In addition, diffusion effects between the glue and the electrodes are prevented that occur given use at high temperatures and that have an influence on the resonance frequencies. However, in this way the mounting and contacting forces, or at least the resultants of all these forces, also act radially on the resonator. Both for thickness shear and for thickness expansion oscillators, an arrangement thereby results in which the mounting and contacting forces act parallel to the node plane of the main oscillation, which can be excited piezoelectrically, whereby these forces also influence the oscillation characteristics only to the smallest possible degree. Of course, at least one of the mounting elements is here also advantageously constructed from one essentially rigid part and one part that can essentially be elastically deformed, the latter part being located closer to the base structure.

According to an additional feature of the invention, the mounting elements can thereby lie immediately and directly on the lateral surface, or on one of the lateral surfaces, of the resonator, by which means it is possible to avoid all axial force components on the covering surfaces of the resonator lamina, and thereby also to avoid all negative influencing of the oscillation characteristics of the resonator.

Advantageously, the points of contact of the mounting elements with the resonator are provided exclusively on the lateral surface, or, respectively, one of the lateral surfaces, of the resonator. That is, the contact points are for example fashioned complementary to the lateral surface or surfaces, or the contact points comprise mounting structures in which resonator laminae can be used having, in principle, any construction of the lateral surfaces B for example, needle-shaped points forming a multipoint mounting, or the like.

According to a further advantageous specific embodiment of the invention, the mounting and contacting forces exerted by the mounting elements are directed essentially radially towards the center of the resonator.

In order to keep the mounting forces, and if necessary also the contacting forces, constant over the entire range of temperatures that will be encountered during use, and also to enable compensation of manufacturing tolerances in the dimensions of the resonator, according to another feature of the invention at least one of the mounting elements is mounted elastically or, respectively, is connected elastically with the base structure.

In an advantageous specific embodiment of the invention, it is provided that at least one of the mounting elements is made up of one essentially rigid part and one part that is essentially elastically deformable, whereby the elastic part is located closer to the base structure. In such arrangement, those parts of the mounting arrangement that are responsible for the magnitude of the mounting forces are arranged outside the region in which temperature changes preferably occur. Here as well, the mounting and contacting forces can be kept essentially constant over the entire application temperature range, and the tolerances can be compensated. For example, given sensor arrangements in which there results a heating of the volume around the resonator, or of the resonator itself, during operation, the elastic part is located at a distance therefrom, so that the heating can act only to a small extent, or not at all, on the mechanical and elastic characteristics of the elastically deformable part of the mounting arrangement. For this reason, the temperature response of the resonance frequency of a piezoelectric resonator in the inventive mount arrangement is influenced only slightly by the mount, and the hysteresis of the resonance frequency is reduced in a temperature range from room temperature up to approximately 700° C.

According to an advantageous specific embodiment of the invention, at least one of the mounting elements is constructed as an oblong mounting arm having at least one essentially rigid longitudinal segment and one segment that is essentially elastically deformable, whereby a good mounting effect and shape endurance is achieved, in particular given the arrangement of the rigid segment at the resonator, and the resonator can be put in place and exchanged easily, since at least one essential segment of the mounting arm can be moved to the side for this purpose, for example using an installation aid.

In contrast, a more stable arrangement can be achieved if at least one essentially rigid mounting element is mounted in elastically resilient fashion at the end of an essentially rigid oblong mounting arm.

If it is provided that the mounting elements are provided with mounting structures that determine a definite orientation of the installed resonator, the advantageous orientation of the resonator in relation to the mounting elements and the forces exerted by them can be ensured with certainty, and the handling, in particular the installation of the resonator in the arrangement, is significantly simplified.

Advantageously, during the installation of the resonator all necessary electrical connections can also be made at the same time if, according to a further feature of the invention, at least one of the mounting elements and/or one of the mounting structures comprises at least one electrical contact surface. However, it is of course also possible for the charging of the resonator with the electrical field that excites the oscillations to take place in contactless fashion or through additional contacts that are provided independent of the mounting elements.

In all of the specific embodiments named above, it is advantageously provided that at least the mounting elements, and preferably also the base structure, are preferably of one-piece construction, made of a ceramic material. This choice of material combines ease of manufacture with the best mechanical and thermal characteristics.

In order to obtain a mounting arrangement that can withstand most application temperature ranges, the necessary electrical lines and contact surfaces on the mounting arrangement are made up of direct coatings of conductive materials. Sputtered-on metal coatings are thereby preferably provided. The temperature stability of the conductor structures is thereby provided up to approximately 800° C.

The object of the present invention is also achieved by an arrangement having a resonator in which at least one of the surface regions is provided with at least one electrode that covers at least a part of this surface region, whereby an electrically conductive strip extends from the electrode, preferably radially, in the direction of the edge of the surface region, and if necessary extends up to the point of immediate contact with the transition region to an adjacent surface region, and which is characterized in that the conductive strip extends from the surface region having the electrode beyond the edge thereof, up to the region of transition to the adjacent surface region. It is thereby no longer necessary to provide a clamping, or even only an electrical contacting, with a force acting normally on the surface, or on each surface, of the resonator having an electrode, in a region thereof that can have an adverse effect on the oscillations characteristics. In an arrangement as specified above, the resonator constructed in this way can be mounted such that the resonance characteristics remain as free as possible of influence from the mounting or, respectively, contacting, and the hysteresis, caused by temperature, of the resonance characteristics is minimized. In addition, the cited features enable the advantageous radial clamping of the resonator while avoiding the contacting of the resonator immediately on the flat surface regions, in advantageous combination with the purely radial mounting and clamping of the resonator.

In the following specification, the invention is explained in more detail on the basis of exemplary embodiments shown in the drawings.

### BRIEF DESCRIPTION OF THE DRAWINGS

FIG. 1 is a side view of the forces on a resonator lamina according to the prior art.

FIG. 2 is a top view of a circular resonator lamina embodying the principles of the present invention and having electrodes and electrically conductive segments extending up to the lateral surface, which is for example essentially cylindrical.

FIG. 3 is a side view of a lamina having beveled lateral surfaces and electrically conductive electrode segments extending up to the node plane.

FIG. 4 is an arrangement having mounting arms that are oriented parallel to the plane of the resonator lamina.

FIG. 5 is an arrangement having mounting arms standing perpendicular to the resonator lamina.

FIG. 6 shows a top view of a flat ceramic lamina as a mounting arrangement.

### DETAILED DESCRIPTION OF THE PREFERRED EMBODIMENTS

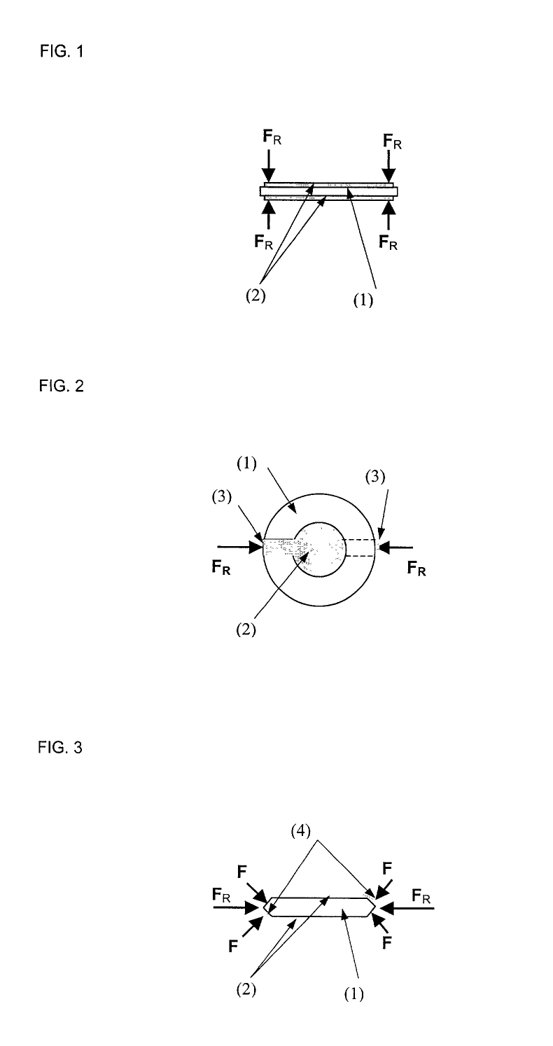

Although other shapes are possible, the preferred shape for piezo electric resonators, in particular for microbalance sensor applications and as frequency standards, is the flat, essentially disk-shaped construction shown in the drawings. Electrodes 2 are thereby applied on the circular resonator lamina 1, as can be seen particularly clearly in FIG. 1. In microbalance arrangements, these electrodes 2 can be provided as an electron collector and counter-electrode. Of course, it is also possible for only one electrode to be present on one side of the resonator lamina 1. The electrode 2, or at least one electrode 2, is applied up to a point close to the edge of the resonator 1. According to the prior art, in an arrangement such as that shown in FIG. 1 the mounting forces or, respectively, contact forces FR at the edge of the resonator in the axial direction therefore act in normal fashion on the node plane of the piezoelectrically excitable main oscillation (thickness shear oscillation or, respectively, thickness expansion oscillation).

In contrast, according to the present invention it is provided that, as shown in FIG. 2, the resonator lamina or plate 1 is borne at its edge by mounting elements that cause forces FR that act radially on the resonator lamina at least two clamping points 3. In this case, the force vectors FR lie in the node plane of the piezoelectrically excitable main oscillation (thickness shear oscillation or, respectively, thickness expansion oscillation). In the resonator 1, the electrodes 2, which cover only a part of the flat surface(s) of the lamina 1, are then preferably provided with conductive strips, called contact lugs 3, which extend out to the lateral surface of the resonator lamina. In this construction of the electrodes, the resonator 1 is held at its edge by radially acting forces FR, and the electrical contact is also produced at the same time by contact surfaces on the mounting elements. Alternatively to this, an electrical contacting separate from the mounting, using separate contact elements, would also be possible. In the inventive arrangement, the force vectors of the mounting forces preferably lie in the node plane of the piezoelectrically excitable main oscillation of the resonator, which comprises a corresponding crystallographic orientation. This holds both for thickness shear oscillations and for thickness expansion oscillations.

In FIG. 3, a resonator 1 is shown having two-way phase at its edge and having an electrode geometry similar to that shown in FIG. 2, but here the contact lugs 4 extend up to the node plane of the main oscillation that is to be excited piezoelectrically (thickness shear oscillation or, respectively, thickness expansion oscillation). In this construction, the mounting or, respectively, contacting forces (F) occur at the phase, whereby the resulting mounting or, respectively, contact forces (FR) again lie parallel to the node plane of the main oscillation that is to be excited piezoelectrically, and therefore act radially on the resonator lamina 1. The peripheral region of the resonator lamina 1, comprising the lateral surfaces, is not flat, but rather is constructed so as to run to an edge, so that, working together with corresponding structures in the mounting elements, a precisely defined orientation of the resonator 1 is determined and can be securely maintained. A construction of this sort also makes handling easier during installation and exchange of the resonator lamina 1, and makes tedious adjustments superfluous.

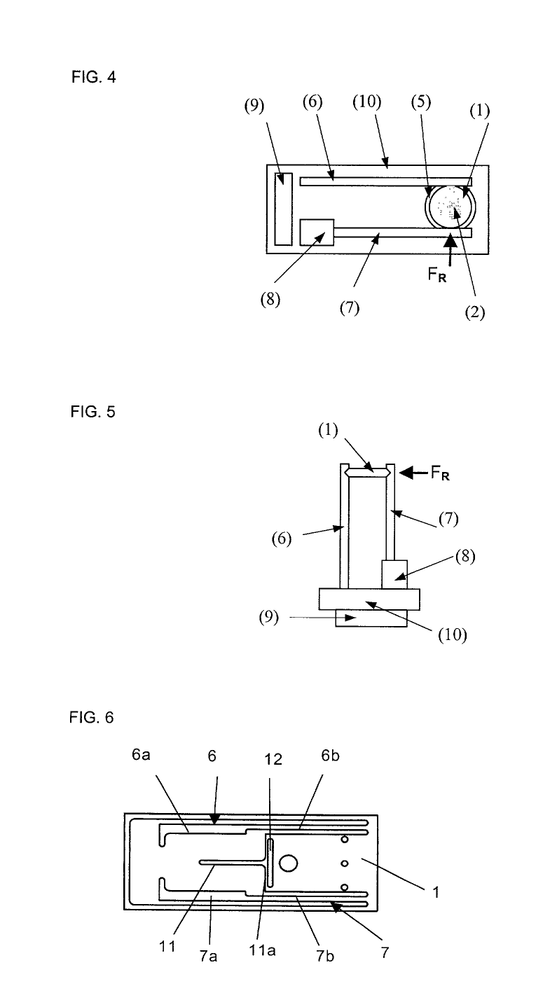

FIG. 4 shows a possible arrangement in which the resonator lamina 1 is located in the plane defined by two oblong mounting arms 6, 7 positioned opposite one another. The mounting arm 6 is thereby of essentially rigid construction, and is preferably also connected fixedly with the base plate 10 of the base structure of the mounting arrangement, while the mounting arm 7, which is likewise essentially rigid, is connected with the base structure via an elastic element 8 or via an elastically deformable longitudinal segment, and in this way exerts holding forces, or, respectively, contacting forces FR on the resonator lamina 1 that are maximally independent of temperature. The electrical contact to the electrodes 2 of the resonator is created via the terminal 9 and the mounting arms 6, 7.

FIG. 5 shows another example of a possible arrangement in which the resonator lamina 1 stands in normal relation to the plane defined by the two mounting arms 6, 7. In this arrangement as well, the mounting forces or, respectively, contacting forces FR are produced by the mounting arm 7, which is connected with the base plate 10 via the elastic element 8, and the electrical contact to the electrodes of the resonator lamina 1 is produced via the terminal 9 and the mounting arms 6, 7. The mounting arm 6 is connected fixedly with the base plate 10.

A further specific embodiment of an inventive mounting arrangement is shown in FIG. 6, in which a top view of a ceramic mounting arrangement is shown. Two oblong mounting arms 6 and 7 are thereby cut from a flat ceramic lamina and are therefore advantageously manufactured in one piece with the base structure 10, said base structure being formed by the segment of the ceramic lamina at the right in the drawing. The mounting arms 6, 7 are made up of two longitudinal segments, of which that longitudinal segment 6a, 7a that comes into contact with the resonator lamina 1, and is also located in the region of the greatest heating, is constructed with a larger cross-section and is therefore essentially rigid. The heating can often be desired and can thereby be particularly intensive, in particular in the case of sensor arrangements and microbalance arrangements. The longitudinal segments 6b, 7b located closer to the base structure 10 are constructed with a smaller cross-section and are therefore elastically deformable, and are responsible for the exertion of the mounting forces, and if necessary also the contacting forces to the electrode 2, on the resonator lamina 1. Since they are located outside the region of the heating of the resonator lamina 1, and in addition can rapidly transmit the brought-in heat to the base structure 10, the mechanical and elastic characteristics thereof are influenced only slightly, or not all, by the temperature changes in the region of the resonator lamina 1.

FIG. 6 shows an advantageous three-point mounting of the resonator lamina 1, whereby in addition to the mounting arms 6, 7 a third mounting arm 11 also appears that is likewise of one-piece construction with the base structure 10, and is likewise fastened elastically to the base structure 10. For this purpose, an oblong hole 12 is provided at the base of the mounting arm 11, said hole being oriented transversely to its longitudinal axis, said hole permitting an elastic axial displacement of the third mounting arm 11.

As is possible on all mounting arrangements, the necessary electrical lines are produced by coatings, preferably sputtered on, of conductive metal, preferably platinum or gold.

In any of the arrangements illustrated, the conductive strips 3, 4 forming the electrodes may be directed to positions on the perimeter of the resonator lamina 1 which minimize the effect of the clamping force on the oscillations, which clamping force is exerted by the supporting arms 6, 7. This optimal position can be calculated using the Ratajski-Coefficient. The basic theory can be found, for example, in M. Mizan & A. Ballato, “The Stress Coefficient of Frequency of Quartz Plate Resonators”, Proc. 37^{th} AFCS p. 194-199, 1983, which is incorporated herein by reference.

Also, via the electrode, such as conductive strips 3, 4, and its conductive connection with the two mounting arms 6, 7, the electrical resistance can be measured and can be used to obtain values of the temperature of the electrode and or the resonator lamina 1, respectively. Further, via the electrode and its conductive connection with the two mounting arms 6, 7, the resonator lamina 1 can be heated or thermally stabilized by leading an electric current therethrough. This heating or thermal stabilizing could be in combination with an arrangement to measure the temperature of the resonator lamina or the area surrounding the resonator lamina and a calculation of the necessary, current value and control of the current source such that the exact required current value is supplied to the electrodes.

As is apparent from the foregoing specification, the invention is susceptible of being embodied with various alterations and modifications which may differ particularly from those that have been described in the preceding specification and description. It should be understood that I wish to embody within the scope of the patent warranted hereon all such modifications as reasonably and properly come within the scope of my contribution to the art.

I claim as my invention:

1. A piezoelectric resonator arrangement comprising a mount having at least two mounting elements and having at least one platelike piezoelectric resonator having at least one excitation electrode from which at least one electrically conductive strip extends in the direction of the edge of the resonator, the resonator being clamped between the mounting elements in a plane, of which at least one element presses on the resonator with a force, said mounting elements abutting immediately and directly on at least one lateral surface of the resonator, wherein the resonator is fixed between the mounting elements without the use of an adhesive, the electrically conductive strip extends at least up to the lateral surface of the resonator, and at least one adhesive-free electrical point of contact with the resonator is provided on the lateral surface of the resonator, the electrical contacting forces lying essentially in one plane with the resonator.

2. An arrangement according to claim 1, wherein the electrical contacting forces exerted by the mounting elements are directed essentially radially to a center of the resonator.

3. An arrangement according to claim 1, wherein on at least one of the mounting elements, at least one electrical contact surface is provided and faces at least one lateral surface of the resonator.

4. An arrangement according to claim 3, wherein on at least two mounting elements, at least one electrical contact surface is respectively provided which faces at least one lateral surface of the resonator, at least one second electrically conductive strip extends radially from at least one excitation electrode of the resonator, and both conductive strips extend to the lateral surface of the resonator and into the region, respectively, of one of the electrical contact surfaces of the mounting elements.

5. An arrangement according to claim 4, wherein the electrical contact surfaces of two mounting elements are connected with one another via at least one arrangement for measuring the electrical resistance.

6. An arrangement according to claim 4, wherein the electrical contact surfaces of two mounting elements are connected with one another via at least one arrangement for the production and regulation of a current flow.

7. An arrangement according to claim 1, wherein at least one of the mounting elements is mounted on a base in an elastically resilient fashion.

8. An arrangement according to claim 1, wherein at least one of the mounting elements is connected with a base structure in an elastically resilient fashion.

9. An arrangement according to claim 1, wherein at least one of the mounting elements is made up of an essentially rigid part and a part that is essentially elastically deformable, whereby the elastic part is located closer to a base structure on which the mounting elements are mounted.

10. An arrangement according to claim 9, wherein at lest one of the mounting elements is constructed as an oblong mounting arm having at least one essentially rigid longitudinal segment and one essentially elastically deformable segment.

11. An arrangement according to claim 9, wherein at least one essentially rigid mounting element is mounted to the base structure in a resilient fashion by means of an elastic element.

12. An arrangement according to claim 1, wherein the mounting elements are provided with mounting structures that determine a definite orientation of the installed resonator, and on which structures the electrical contact surfaces are provided.

13. An arrangement according to claim 1, wherein at least one of the mounting elements is manufactured from ceramic material.

14. An arrangement according to claim 12, wherein the mounting elements are mounted on a base structure and the base structure is manufactured from a ceramic material.

15. An arrangement according to claim 13, wherein the mounting elements and the base structure comprise a one-piece construction.

16. An arrangement according to claim 1, wherein electrical lines and contact surfaces on the mounting arrangement are provided that are made of direct coatings of electrically conductive materials.

17. An arrangement according to claim 1, wherein the at least one electrically conductive strip extends radially.

18. A piezoelectric resonator arrangement comprising a mount having at least two mounting elements on a base structure and having at least one platelike piezoelectric resonator clamped between the mounting elements, of which at least one mounting element presses on the resonator with a force, wherein the mounting elements abut immediately and directly on the resonator and fix the resonator in the arrangement without the use of an adhesive, the points of contact of the mounting elements with the resonator lie essentially in one plane, said plane being essentially parallel to a plane of the resonator, and the mounting and contacting forces exerted by the mounting elements lie essentially parallel to the plane of the resonator.

19. An arrangement according to claim 18, wherein the points of contact of the mounting elements with the resonator are provided exclusively on at least one lateral surface of the resonator.

20. An arrangement according to claim 18, wherein the resonator has at least one surface region which is provided with at least one electrode that covers at least one part of this surface region, whereby an electrically conductive strip extends from the electrode in the direction of an edge of the surface region, wherein the conductive strip extends from the surface region having the electrode beyond the edge thereof, up to a region of transition to an adjacent surface region.
